(19) United States
(12) Patent Application Publication
(10) Pub. No.: US 2024/0363388 A1
(43) Pub. Date: Oct. 31, 2024

(54) PACKAGE PICK-UP APPARATUS AND METHODS FOR USING THE SAME

(71) Applicant: Taiwan Semiconductor Manufacturing Company Limited, Hsinchu (TW)

(72) Inventors: Hsin Liang Chen, New Taipei City (TW); Ching-Hua Hsieh, Hsinchu (TW); Hsiu-Jen Lin, Zhubei City (TW); Hsuan-Ting Kuo, Taichung City (TW); Wei-Yu Chen, Hsinchu (TW); Cheng-Shiuan Wong, Hsinchu City (TW)

(21) Appl. No.: 18/307,036

(22) Filed: Apr. 26, 2023

(51) Int. Cl. H01L 21/683; H01L 21/67

(52) U.S. Cl. CPC H01L 21/6838; H01L 21/67092; H01L 21/67144; H01L 21/67253

(57) ABSTRACT

An adhesion film with a plurality of semiconductor packages thereupon may be positioned on a pedestal including an enclosure and having a perforated top surface, a first support ring located at a periphery of the perforated top surface, and a second support ring laterally surrounding the first support ring. A first semiconductor package overlaps segments of the first support ring at a plurality of overlap areas in a top-down view, and does not contact the second support ring in the top-down view. A vacuum suction may be applied to a volume within the enclosure and to a gap which is vertically bounded by a bottom surface of the adhesion film and is laterally bounded by the first support ring while holding the first semiconductor package stationary. A portion of the adhesion film underlying the first semiconductor package is peeled off a bottom surface of the first semiconductor package.

### BACKGROUND

Upon dicing of semiconductor packages, the semiconductor packages may be individually picked up through detachment from an adhesion film. The present disclosure provides a semiconductor package pick-up apparatus for package pick-up and adhesion film peeling from an assembly of packages and an adhesion film.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a semiconductor package pick-up apparatus after placement and alignment of semiconductor packages on an adhesion film over a pepper pot according to an embodiment of the present disclosure.

FIG. 1B is a see-through top-down view of the semiconductor package pick-up apparatus of FIG. 1A. The adhesion film is schematically represented by a dotted area. A top suction gear is omitted in the view of FIG. 1B.

FIG. 1C is a see-through top-down view of an alternative configuration of the semiconductor package pick-up apparatus of FIG. 1A. The adhesion film is schematically represented by a dotted area. A top suction gear is omitted in the view of FIG. 1B.

FIG. 1D is a zoom-out top-down view of the semiconductor packages on the adhesion film in FIG. 1A.

FIG. 1E is a vertical cross-sectional view of an example of a semiconductor package within the two-dimensional array of semiconductor packages in FIGS. 1A-1C.

FIG. 2A is a vertical cross-sectional view of the semiconductor package pick-up apparatus after placing and actuating the top suction gear on a semiconductor package according to an embodiment of the present disclosure.

FIG. 2B is a see-through top-down view of the semiconductor package pick-up apparatus of FIG. 2A. The adhesion film is schematically represented by a dotted area.

FIG. 2C is a see-through top-down view of an alternative configuration of the semiconductor package pick-up apparatus of FIG. 2A. The adhesion film is schematically represented by a dotted area.

FIG. 3 is a vertical cross-sectional view of the semiconductor package pick-up apparatus during an initial phase of peeling a portion of the adhesion film underneath the semiconductor package according to an embodiment of the present disclosure.

FIG. 4 is a vertical cross-sectional view of the semiconductor package pick-up apparatus during a middle phase of peeling the portion of the adhesion film underneath the semiconductor package according to an embodiment of the present disclosure.

FIG. 5 is a vertical cross-sectional view of the semiconductor package pick-up apparatus during a terminal phase of peeling the portion of the adhesion film underneath the semiconductor package according to an embodiment of the present disclosure.

FIG. 6 is a vertical cross-sectional view of the semiconductor package pick-up apparatus during a middle phase of peeling the portion of the adhesion film underneath the semiconductor package in an alternative operational mode according to an embodiment of the present disclosure.

FIG. 7A is a vertical cross-sectional view of a semiconductor package pick-up apparatus after placement and alignment of a two-dimensional array of semiconductor packages on an adhesion film over a pepper pot according to an embodiment of the present disclosure.

FIG. 7B is a see-through top-down view of the semiconductor package pick-up apparatus of FIG. 7A. The adhesion film is schematically represented by a dotted area. A top suction gear is omitted in the view of FIG. 7B.

FIG. 7C is a see-through top-down view of an alternative configuration of the semiconductor package pick-up apparatus of FIG. 7A. The adhesion film is schematically represented by a dotted area. A top suction gear is omitted in the view of FIG. 7B.

FIG. 8A is a vertical cross-sectional view of the semiconductor package pick-up apparatus after placing and actuating the top suction gear on a semiconductor package according to an embodiment of the present disclosure.

FIG. 8B is a see-through top-down view of the semiconductor package pick-up apparatus of FIG. 8A. The adhesion film is schematically represented by a dotted area.

FIG. 8C is a see-through top-down view of an alternative configuration of the semiconductor package pick-up apparatus of FIG. 8A. The adhesion film is schematically represented by a dotted area.

FIG. 9 is a graph illustrating the changes in the pressure in an enclosure within a pepper pot of the semiconductor package pick-up apparatus of the present disclosure during peeling of a portion of an adhesion film according to an embodiment of the present disclosure.

FIG. 10 is a first flowchart illustrating steps for operating the semiconductor package pick-up apparatus according to an embodiment of the present disclosure.

FIG. 11 is a second flowchart illustrating steps for operating the semiconductor package pick-up apparatus according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to a semiconductor package pick-up apparatus including a pedestal (such as a pepper pot) and a vacuum system that may be used for a wafer-to-tray process, i.e., a process in which semiconductor packages are picked up from an adhesive film and stored for further processing such as attachment to packaging substrates. The semiconductor packages may be individually peeled off the adhesive film using a pedestal and a soft vacuum application method that reduces the bending stress exerted on the semiconductor packages. Peeling of the adhesion film and semiconductor package pick-up may be performed in an integrated peel-off and pick-up apparatus in a manner that eliminates or reduces after-tacks, i.e., residual portions of an adhesive film.

As the size of semiconductor packages increases, the force used to pick up a semiconductor package typically increases. As a result, the likelihood that the semiconductor package is mechanically distorted during pick-up also increases. In various embodiment semiconductor package pick-up apparatus of the present disclosure, a first support ring may be provided at a periphery of a perforated top surface of a pedestal, and may be used to define a boundary of a vacuum cavity and to provide structural support to a semiconductor package. A soft vacuum may be generated in the vacuum cavity to peel a portion of the adhesion film that underlies the semiconductor package. The magnitude of the soft vacuum may be adjusted to minimize the force applied to the semiconductor package during the process of peeling the semiconductor package from the adhesion film. The semiconductor package may be pulled up after peeling the adhesion film. In this manner, needles or mechanical push-up structures are not used during extraction of the semiconductor package. The various embodiment semiconductor package pick-up apparatus of the present disclosure may eliminate or reduce after-tacks (i.e., residual portions of an adhesion film), and may pick up semiconductor packages at a high throughput, which may be about 10 seconds per semiconductor package, using a single semiconductor package pick-up apparatus.

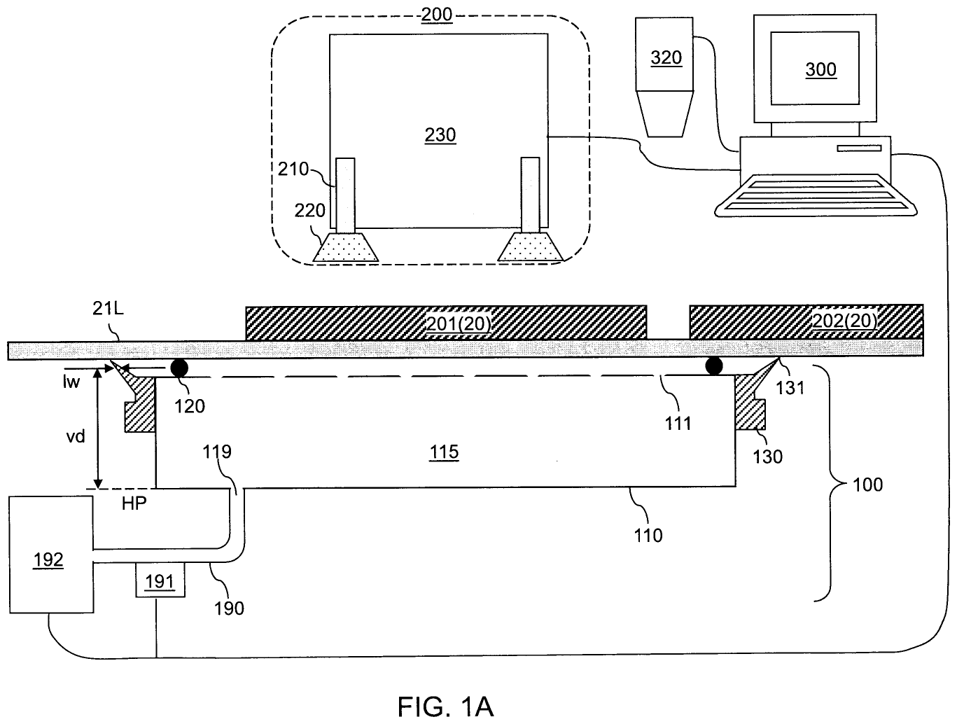

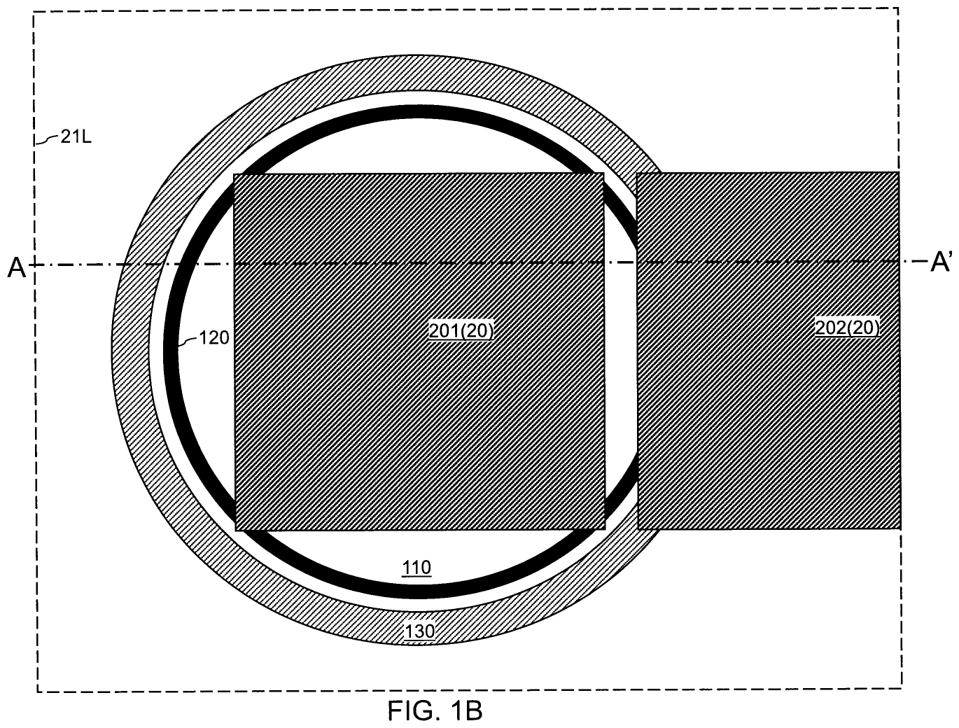

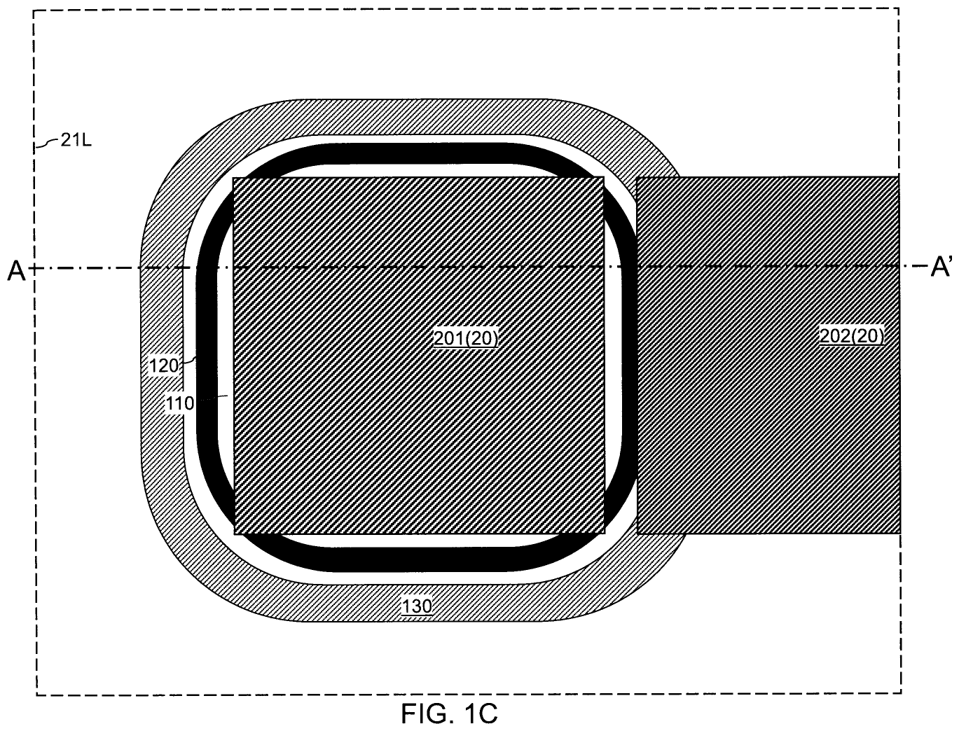

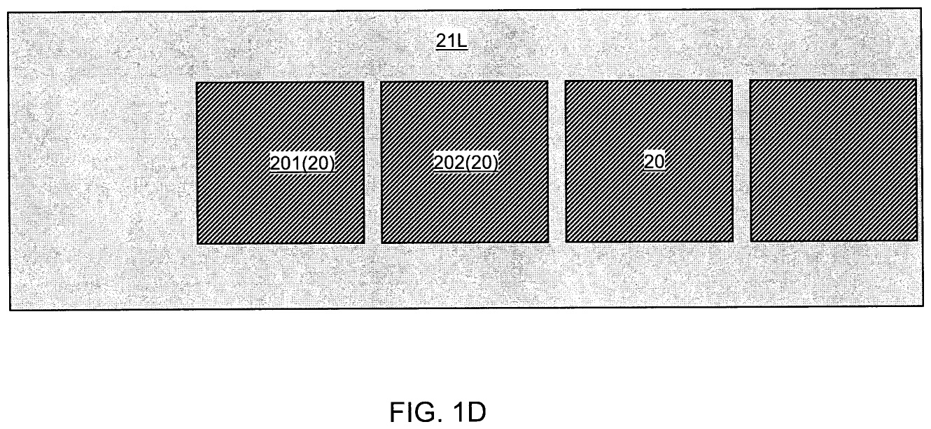

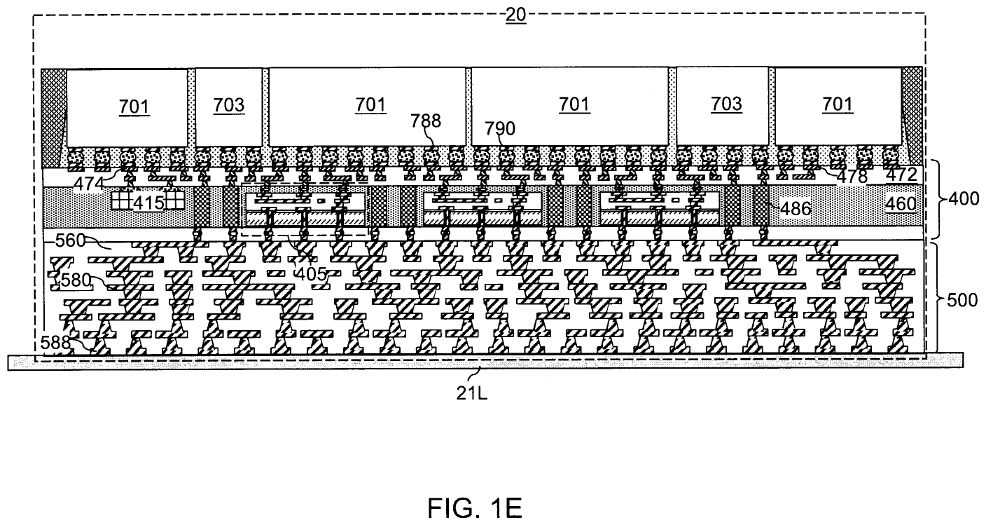

FIG. 1A is a vertical cross-sectional view of a semiconductor package pick-up apparatus after placement and alignment of semiconductor packages 20 on an adhesion film 21L over a pepper pot according to an embodiment of the present disclosure. FIG. 1B is a see-through top-down view of the semiconductor package pick-up apparatus of FIG. 1A. The adhesion film 21L is schematically represented by a dotted line area. A top suction gear is omitted in the view of FIG. 1B. FIG. 1C is a see-through top-down view of an alternative configuration of the semiconductor package pick-up apparatus of FIG. 1A. The adhesion film 21L is schematically represented by a dotted line area. A top suction gear is omitted in the view of FIG. 1C. FIG. 1D is a zoom-out top-down view of the semiconductor packages 20 on the adhesion film 21L in FIG. 1A. FIG. 1E is a vertical cross-sectional view of an example of a semiconductor package 20 within the two-dimensional array of semiconductor packages 20 in FIGS. 1A-1C.

Referring collectively to FIGS. 1A-1E, an embodiment semiconductor package pick-up apparatus is provided, which comprises a bottom unit 100 and a top unit (200, 320). The bottom unit 100 comprises a pedestal 110 including an enclosure and having a perforated top surface, a first support ring 120 located at a periphery of the perforated top surface, and a second support ring 130 located at an upper portion of an outer sidewall of the pedestal 110 and laterally surrounding the first support ring 120. The enclosure may have a pepper pot configuration, which is a configuration including the perforated top surface, a bottom surface that is parallel to the perforated top surface, and at least one sidewall extending between the perforated top surface and the bottom surface and laterally surrounding an enclosed volume 115. In one embodiment, the enclosed volume 115 may be a cylindrical volume having a horizontal cross-sectional shape of a circle, a rounded rectangle, an oval, an ellipse, or a generally curvilinear two-dimensional shape having a single closed periphery within which a rectangular horizontal cross-sectional shape of a semiconductor package.

The perforated top surface of the pedestal 110 may have a plurality of openings 111 therethrough. In one embodiment, the openings 111 may be located entirely within the area of the first support ring 120. The enclosure defined by the pedestal 100 is connected to a vacuum line 190 through a vacuum orifice 119. The vacuum line 190 may be connected to the enclosed volume 115 through the bottom surface of the pedestal 100 (as shown in FIG. 1A), or through a sidewall of the pedestal 100 (not shown). A pressure sensor 191 may be attached to the enclosed volume 115 (not shown), or may be attached to the vacuum line 190 (as shown in FIG. 1A). The vacuum line 190 may be connected to a vacuum pump 192 located on the facility side in a fabrication facility.

In one embodiment, the first support ring 120 may be laterally offset inward from the periphery of the perforated top surface of the pedestal 110. In one embodiment, the lateral offset distance between the first support ring 120 and the periphery of the perforated top surface of the pedestal 110 may be uniform, and may be in a range from 0.2 mm to 5 mm, such as from 0.4 mm to 2.5 mm, although lesser and greater lateral offset distances may also be used. In one embodiment, the first support ring 120 may have a circular or elliptical vertical cross-sectional profile. The first support ring 120 may be formed of any suitable durable polymer material.

The second support ring 130 may laterally surround the pedestal 110, and may be located outside a vertical plane containing the sidewall(s) of the pedestal 110. In one embodiment, the second support ring 130 may have an inner sidewall and an outer sidewall. The inner sidewall may comprise a first tapered annular surface, and the outer sidewall may comprise a second tapered annular surface having a lesser taper angle than the first tapered annular surface (as measured from a vertical direction). In one embodiment, the second support ring 130 has a vertical cross-sectional profile in which a lateral width between an inner sidewall and an outer sidewall decreases with an increase in the vertical distance vd from a horizontal plane HP including a bottom surface of the pedestal 110. The second support ring 130 may comprise a top rim 131, which may be the highest portion of the second support ring 130. According to an aspect of the present disclosure, the top rim 131 of the second support ring 130 may be located within a same horizontal plane as a topmost surface of the first support ring 120. The second support ring 130 may be formed of any suitable durable polymer material.

The semiconductor package pick-up apparatus may comprise a process controller 300 that is loaded with a vacuum suction control program. The process controller 300 may be configured to apply a vacuum suction to a volume located inside the enclosure, i.e., the enclosed volume 115 through vacuum line 190 and vacuum pump 192. The vacuum suction control program may be configured to provide a temporally-increasing change in a magnitude of the vacuum suction that is generated in the enclosed volume 115 inside the pedestal 110 during operation.

The top unit (200, 320) comprises a package movement control unit 200. The package movement control unit 200 is configured to control vertical movement of a semiconductor package 20 that is positioned underneath. In one embodiment, the package movement control unit 200 may comprise a vacuum gear (210, 220) configured to provide a vacuum suction to a top surface of the semiconductor package 20 that is placed underneath. The vacuum gear (210, 220) may be located above the pedestal 110, and may be attached to a vacuum gear actuator 230 configured to provide a vertical movement to the vacuum gear (210, 220). The vacuum gear (210, 220) may comprise at least one vacuum suction cup 220 and at least one vacuum tube 210 attached to a respective vacuum suction cup 220. Each vacuum suction cup 220 may be configured to be attached to a top surface of a semiconductor package 20. The vacuum gear actuator 230 may be configured to lower the vacuum gear (210, 220) onto an underlying semiconductor package 20, and to lift the combination of the vacuum gear (210, 220) and the underlying semiconductor package 20 after an adhesive film 21L is detached from the underlying semiconductor package 20. The process controller 300 may be configured to initiate and to terminate the vacuum suction at each vacuum suction cup 220, and to control the vacuum gear actuator 230.

The top unit (200, 320) may further comprise an optical camera 320 configured to monitor movement of a portion of an adhesion film 21L that is located between a neighboring pair of semiconductor packages 20. An image analysis program may be loaded onto the process controller 300, and may be configured to detect delamination of an adhesion film 21L from a semiconductor package 20. The adhesion film 21L may comprise a polyimide-based adhesion film as known in the art.

The process controller 300 may be any type of computing device including a processor and memory elements in communication with the processor. The process controller 300 may comprise a single computing device, or may comprise a plurality of computing devices that are interconnected to one another. The process controller 300 may be a stand-alone computing device, a networked computing device, and/or a mobile computing device. Generally, the process controller 300 may be loaded with all necessary programs for automatic execution of the various movements and pressure changes of the various elements of the semiconductor package pick-up apparatus of the present disclosure.

In one embodiment, the process controller 300 may be configured to provide a temporally-increasing change in the magnitude of the vacuum suction that is applied to the enclosed volume 115 until detection of delamination of the adhesion film 21L from a semiconductor package 20 located underneath the package movement control unit 200. Further, the process controller 300 may be configured to maintain the magnitude of the vacuum suction applied to the enclosed volume 115 at a constant level upon detection of the delamination for a predetermined duration of time that is sufficient to ensure delamination of the adhesion film 21L from a center portion of a bottom surface of a semiconductor package 20. In addition, the process controller 300 may be configured to provide a signal to the vacuum gear actuator 230 for lifting up the vacuum gear (210, 220) and an underlying semiconductor package 200 after a predetermined duration of time that follows the detection of the delamination while maintaining a vacuum suction on the underlying semiconductor package 200 and while maintaining a vacuum suction on the enclosed volume 115.

During operation of an embodiment semiconductor package pick-up apparatus of the present disclosure, an adhesion film 21L with a plurality of semiconductor packages 20 thereupon may be provided. The adhesion film 21L with the plurality of semiconductor packages 20 may be placed on the pedestal 110. The adhesion film 21L may be provided as an adhesion film strip extending along a horizontal lengthwise direction, and the plurality of semiconductor packages 20 may be provided as a one-dimensional periodic array of semiconductor packages 20. Alternatively, the adhesion film 21L may be provided as an adhesion film layer, and the plurality of semiconductor devices 20 may be provided as a two-dimensional periodic array of semiconductor packages 20. The adhesion film 21L with the plurality of semiconductor packages 20 may be positioned such that a first semiconductor package 201 selected from the plurality of semiconductor packages 20 has an areal overlap with segments of the first support ring 120 at a plurality of overlap areas (such as four overlap areas as illustrated in FIGS. 1B and 1C) in a top-down view, and does not have any areal overlap with the second support ring 130 in the top-down view. FIGS. 1A-1D illustrate configurations in which all semiconductor packages provided at the left side of the first semiconductor package 201 loaded onto the pedestal 110 are removed prior to loading the first semiconductor package 201 onto the pedestal 110, while semiconductor packages 20 provided at the right side of the first semiconductor package are still attached to the adhesion film 21L.

The adhesion film 21L with the plurality of semiconductor packages 20 thereupon may be positioned on the pedestal 110 such that first portions of the first support ring 120 support a first semiconductor package 201 selected from the plurality of semiconductor packages 20, and second portions of the first support ring 120 and portions of the second support ring 130 support a second semiconductor package 202 selected from the plurality of semiconductor packages 20.

In one embodiment, the first semiconductor package 201 may be positioned such that corner portions of the first semiconductor package 201 are located between the first support ring 120 and the second support ring 130 in a top-down view of the pedestal 110. In one embodiment, sidewalls of the first semiconductor package 201 comprise segments that are located within an area defined by an inner periphery of the first support ring 120 in a top-down view upon positioning the adhesion film 21L on the pedestal 110 (which may be referred to as a “pepper pot”). In one embodiment, the plurality of overlap areas are located at four corner regions of the first semiconductor package 201 in the top-down view. In one embodiment, the first semiconductor package 201 may be positioned such that an entirety of the first semiconductor package 201 is located within an area defined by an inner periphery of the second support ring 130 in the top-down view.

In one embodiment, the adhesion film 21L may be positioned such that a portion of the first support ring 120 and a portion of the second support ring 130 underlie, and support, a second semiconductor package 202 selected from the plurality of semiconductor packages 20. In one embodiment, a portion of the adhesion film 21L located between the first semiconductor package 201 and the second semiconductor package 202 may comprise a first area located inside the first support ring 120, second areas having a respective areal overlap with the first support ring 120 in the top-down view, and third areas located outside the first support ring 120. Generally, the adhesion film 21L may be positioned such that a vacuum suction may be applied to a segment of the adhesion film 21L located in the first area and is not applied to segment of the adhesion film 21L located in the third area.

Generally, any type of semiconductor packages 20 on an adhesive film 21L may be used for the purpose of the present disclosure. FIG. 1E illustrates a non-limiting example of a semiconductor package 20, which may comprise a composite interposer (500, 400) including a stack of an organic interposer 500 and an embedded die interconnect bridge (EMIB) interposer 400 (also referred to local silicon interconnect interposer), and at least one semiconductor die (701, 703) that is attached to the composite interposer (500, 400).

The organic interposer 500 may comprise redistribution wiring interconnects 580 embedded in redistribution dielectric layers 560. Package-side bonding structures 588 (such as C4 bonding pads) may be located on one side of the organic interposer 500.

The EMIB interposer 400 may comprise at least one embedded dies 405, which may comprise at least one local silicon interconnects. Generally, each of the embedded dies 405 may comprise passive interconnect structures (without transistors therein), or may comprise active interconnect structures (with transistors therein). The EMIB interposer 400 may further comprise through-fan-out via structures 486 (which are also referred to through-fan-out via structures 486). A molding compound (MC) interposer frames 460 may laterally surround the through-fan-out via structures 486 and the embedded dies 405. Further, the EMIB interposer 400 may comprise die-side redistribution dielectric layers 472, die-side redistribution wiring interconnects 474, at least one optional surface mount die 415, and on-interposer bump structures 478.

The at least one semiconductor die (701, 703) may comprise at least one system-on-chip (SoC) die 701 and/or at least one memory die 703 (which may comprise at least one high bandwidth (HBM) die). The at least one semiconductor die (701, 703) may be attached to the on-interposer bump structures 478 of the composite interposer (500, 400) via at least one array of on-die bump structures 788 and at least one array of solder material portions 790. In one embodiment, one, a plurality, and/or each, of the at least one array of on-die bump structures 788 may comprise a respective array of copper pillars (such as C2 bonding pillars).

Generally, any alternative semiconductor package 20 may be used in lieu of the semiconductor package 20 illustrated in FIG. 1E for the purpose of implementing embodiments of the present disclosure.

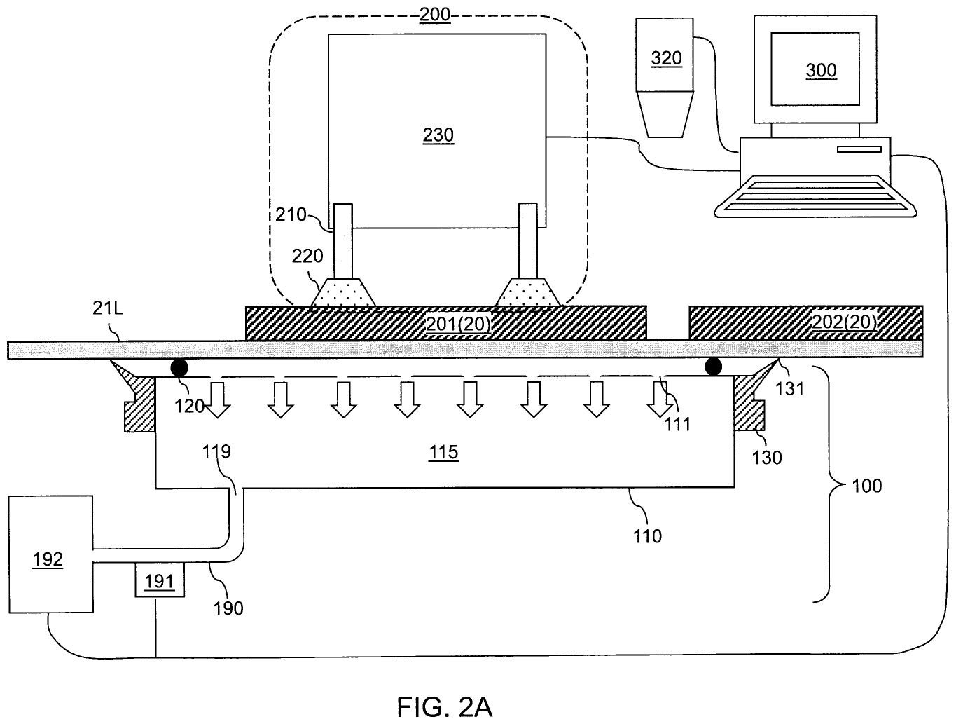

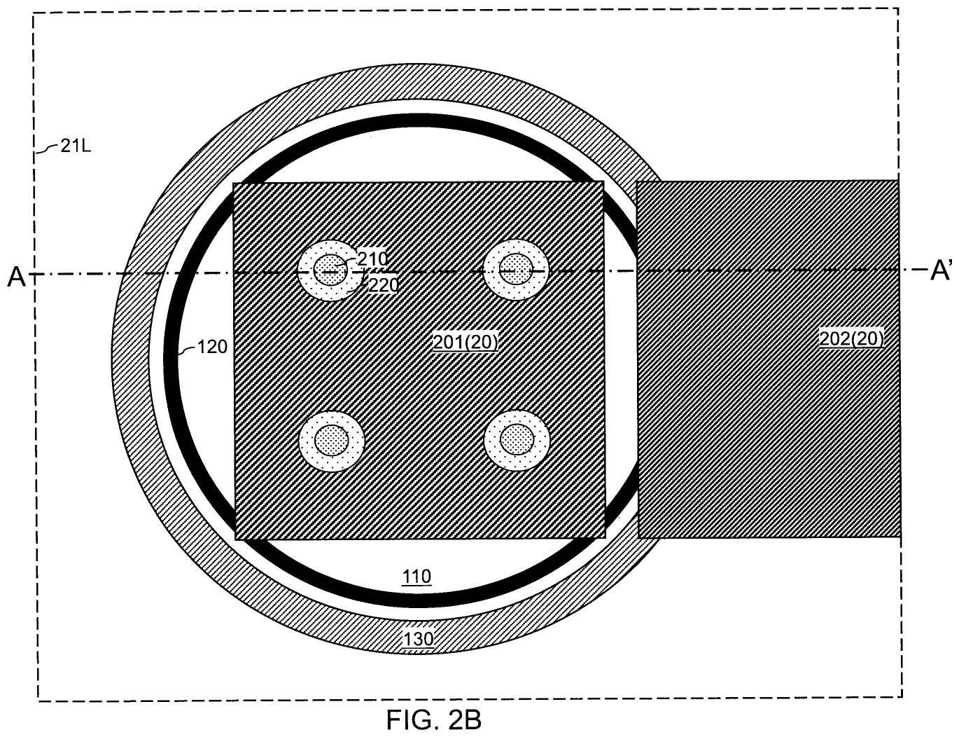

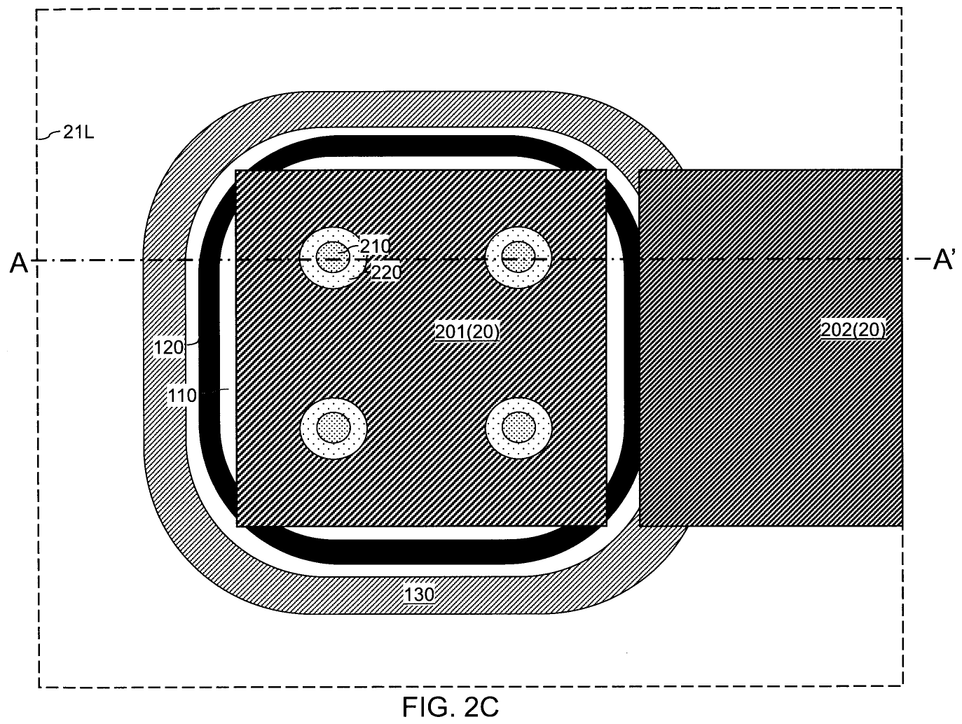

FIG. 2A is a vertical cross-sectional view of the semiconductor package pick-up apparatus after placing and actuating the top suction gear on a semiconductor package 20 according to an embodiment of the present disclosure. FIG. 2B is a see-through top-down view of the semiconductor package pick-up apparatus of FIG. 2A. The adhesion film 21L is schematically represented by a dotted area. FIG. 2C is a see-through top-down view of an alternative configuration of the semiconductor package pick-up apparatus of FIG. 2A. The adhesion film 21L is schematically represented by a dotted area.

The vacuum gear (210, 220) may be lowered onto the top surface of the first semiconductor package 201 by actuating the vacuum gear actuator 230. Upon contact between the vacuum suction cup(s) 220 and the first semiconductor package 201, a vacuum suction may be applied to the vacuum suction cup(s) 220 so that the first semiconductor package 201 may be held stationary. Thus, a first vacuum suction may be applied to the first semiconductor package 201 to keep the first semiconductor package 201 stationary, and a second vacuum suction may be applied to the enclosed volume 115 within the pedestal 110 and to a portion of the bottom surface of the adhesion film 21L that underlies the first semiconductor package 201.

The lateral position of the adhesion film 21L relative to the pedestal 110 may be fixed by turning on the vacuum suction in the enclosed volume 115. The vacuum suction is applied to a segment of the bottom surface of the adhesion film 21L that is located within the area of the first support ring 120 in the top-down view through the plurality of openings 111 in the perforated top surface of the pedestal 110.

Generally, a vacuum suction may be applied to a volume within the enclosure of the pedestal 110 and to a gap which is vertically bounded by a bottom surface of the adhesion film 21L and is laterally bounded by the first support ring 120 while holding the first semiconductor package 201 stationary. In one embodiment, the first semiconductor package 201 may be held stationary by positioning a vacuum gear (210, 220) onto a top surface of the first semiconductor package 201, and by applying a vacuum suction to the top surface of the semiconductor package 20.

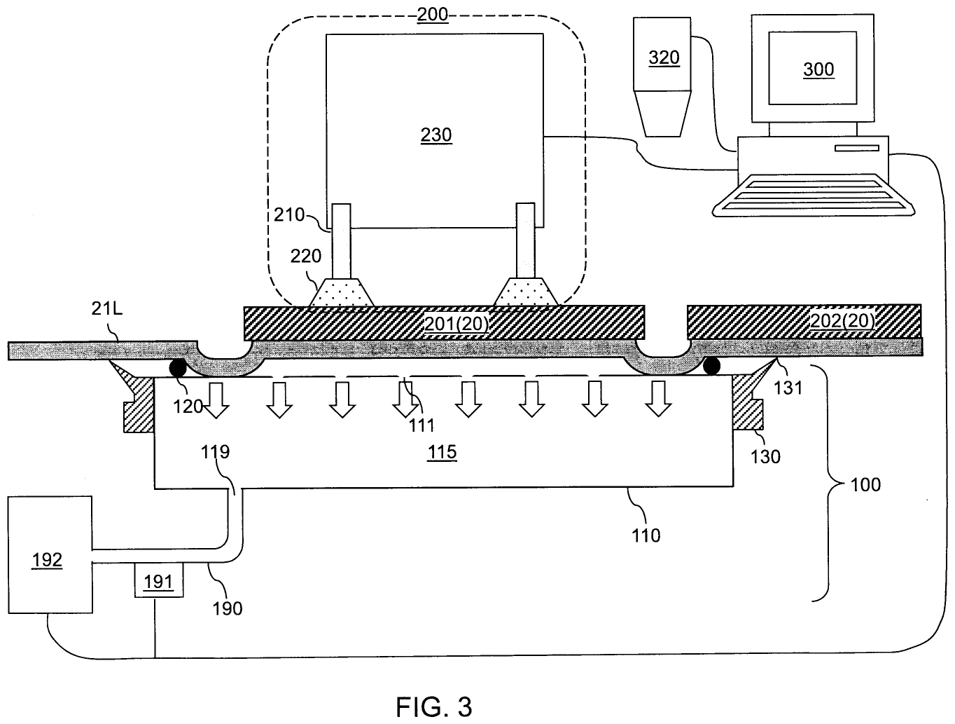

FIG. 3 is a vertical cross-sectional view of the semiconductor package pick-up apparatus during an initial phase of peeling a portion of the adhesion film 21L underneath the semiconductor package 20 according to an embodiment of the present disclosure.

Referring to FIG. 3, the vacuum suction on the enclosed volume 115 and the gap may be applied with a temporal change such that a magnitude of a force applied to a portion of the adhesion film 21L that underlies the first semiconductor package 201 increases until local peeling of the adhesion film 21L begins to peel at a periphery of the bottom surface of the first semiconductor package 201. Generally, the temporal change in the vacuum suction may be stepwise, linear, or may be otherwise modulated in time in a manner that increases the magnitude of the vacuum suction, i.e., in a manner that increases the magnitude of the downward force applied to the portion of the adhesion film 21L that underlies the first semiconductor package 201. In this embodiment, the process controller 300 may be loaded with a vacuum suction control program that is configured to provide a temporally-increasing change in the magnitude of the vacuum suction to the enclosed volume 115 and the gap underlying the first semiconductor package 110 during operation of the semiconductor package pick-up apparatus.

In one embodiment, a portion of the adhesion film 21L that is not covered by the first semiconductor package 201 and is proximate to the first semiconductor package 201 may be optically monitored while increasing the magnitude of the vacuum suction to the enclosed volume 115 and the gap underlying the first semiconductor package 110. The optical monitoring of the adhesion film 21L may be effected by the optical camera 320. In an illustrative example, the optical camera 210 may monitor a portion of the adhesion film 21L located between the first semiconductor package 201 and the second semiconductor package 202.

As the magnitude of the vacuum suction applied to the enclosed volume 115 and the gap underlying the first semiconductor package 110 increases, a portion of the adhesion film 21L underlying the first semiconductor package 201 may be peeled off the bottom surface of the semiconductor package 20. In one embodiment, the magnitude of the vacuum suction applied to the enclosed volume 115 and the gap underlying the first semiconductor package 110 may be held at a steady value upon detection of commencement of peeling off of the adhesion film 21L within an optically monitored portion of the adhesion film 21L. The magnitude of the vacuum suction applied to the vacuum suction cup(s) 220 may remain the same until complete detachment of the first semiconductor package 201 from the adhesion film 21L.

Generally speaking, the first support ring 120 defines a boundary of a vacuum cavity that is formed underneath the adhesion film 21L. The force differential across a first portion of the bottom surface of the adhesion film 21L located inside the area of the first support ring 120 in a top-down view and a second portion of the bottom surface of the adhesion film 21L located outside the area of the first support ring causes a force differential across the first support ring 120, and causes the adhesion film 21L to peel from areas that are not covered by the semiconductor packages 20.

The vacuum applied to the enclosed volume 115 and the gap underlying the first semiconductor package 110 at the time of commencement of, and during, the peeling-off of the portion of the adhesion film 21L located inside the area of the first support ring 120 may be a “soft vacuum,” i.e., a partial vacuum that applies a pressure difference that is less than 100% of the average atmospheric pressure (which is 1.013×105 Pascal). According to embodiments of the present disclosure, the partial vacuum applied to the portion of the adhesion film 21L located inside the area of the first support ring 120 may be in a range of 0.05 times the atmospheric pressure to 0.95 times the atmospheric pressure, such as from 0.10 times the atmospheric pressure to 0.90 times the atmospheric pressure, and/or from 0.30 times the atmospheric pressure to 0.70 times the atmospheric pressure. Accordingly, the pressure differential between the physically exposed portion of the top surface of the adhesion film 21L and the portion of the bottom surface of the adhesion film 21L that is exposed to a gap between the adhesion film 21L and the perforated top surface of the pedestal may be in a range of 0.05 times the atmospheric pressure to 0.95 times the atmospheric pressure, such as from 0.10 times the atmospheric pressure to 0.90 times the atmospheric pressure, and/or from 0.30 times the atmospheric pressure to 0.70 times the atmospheric pressure. Because less than a full vacuum is used to peel off the adhesion film 21L from the bottom surface of the first semiconductor package 201, the first semiconductor package 201 is subjected to a less force than a force that would be generated if full vacuum were to be applied to the backside of the adhesion film 21L.

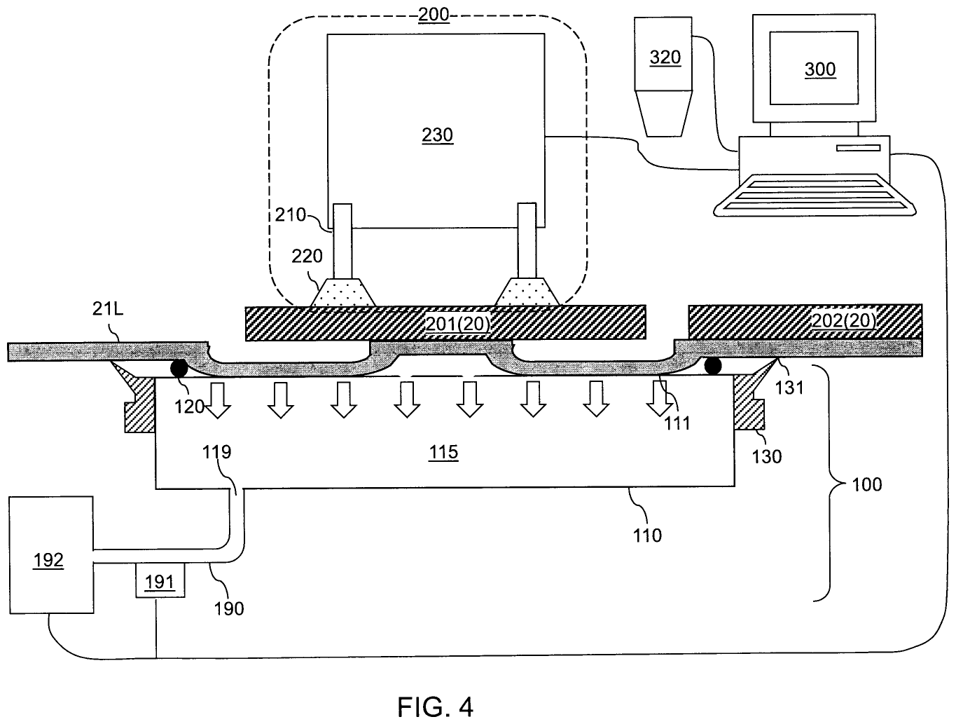

FIG. 4 is a vertical cross-sectional view of the semiconductor package pick-up apparatus during a middle phase of peeling the portion of the adhesion film 21L underneath the semiconductor package 20 according to an embodiment of the present disclosure.

Referring to FIG. 4, the vacuum suction applied to the gap between the perforated top surface of the pedestal 110 and the portion of the adhesion film 21L located within the area of the first support ring 120 may remain steady at the value at which the delamination of the adhesion film 21L is detected, or alternatively, at a level that is offset from the detected vacuum level by a predetermined offset level (e.g., at a vacuum level that applies a force that is in a range from 100.5% to 120% of the force to the adhesion film 21L that initiates the delamination of the adhesion film 21L). Further, the vacuum suction applied to the gap between the perforated top surface of the pedestal 110 and the portion of the adhesion film 21L located within the area of the first support ring 120 may be maintained for a predetermined duration of time. The predetermined duration of time may be determined based on empirical data on the time it takes for an adhesion film to be detached from a center portion of semiconductor packages having a same size as the first semiconductor package 201. For example, the predetermined duration of time may be in a range from 0.3 second to 10 seconds, such as from 1 second to 5 seconds.

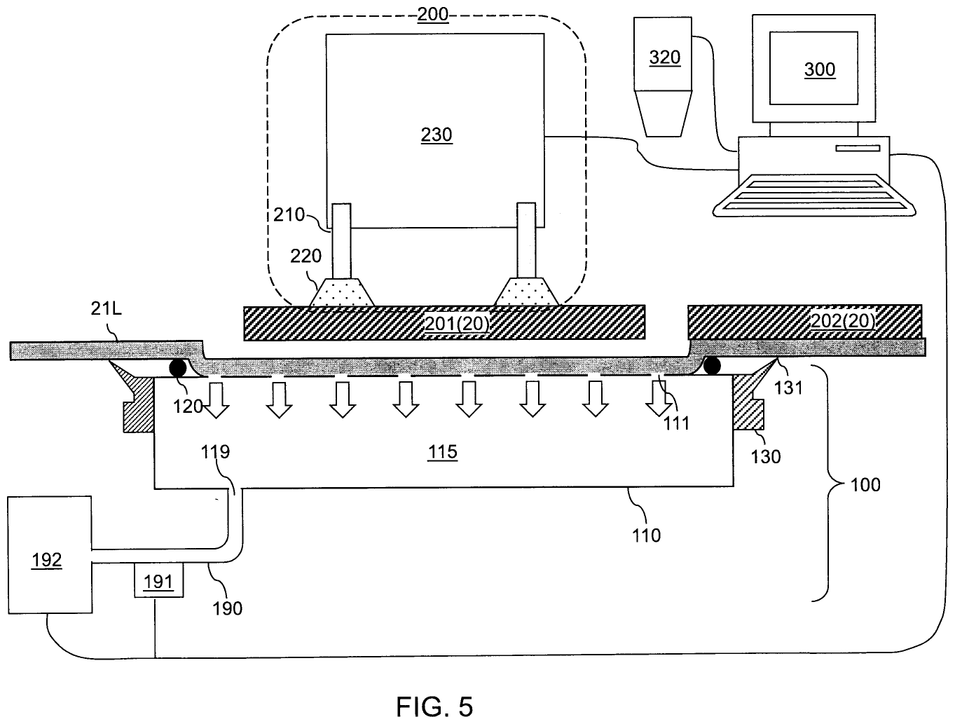

FIG. 5 is a vertical cross-sectional view of the semiconductor package pick-up apparatus during a terminal phase of peeling the portion of the adhesion film 21L underneath the semiconductor package 20 according to an embodiment of the present disclosure.

Referring to FIG. 5, the semiconductor package pick-up apparatus is illustrated after the adhesion film 21L is detached from the center portion of the first semiconductor package 201 at the end of the predetermined duration of time. At this point, the first semiconductor package 201 may be attached to the adhesion film 21L only at locations that overlie the first support ring 120 or located outside the area of the first support ring 120 in a top-down view.

Subsequently, the first semiconductor package 201 may be lifted while a first vacuum suction is applied to the vacuum suction cup(s) 220 and a second vacuum suction is applied to the enclosed volume 115 and the portion of the backside of the adhesion film 21L that overlies the openings 111 in the perforated top surface of the pedestal 110. Portions of the adhesion film 21L overlying the first support ring 120 are detached as the first semiconductor package 201 is lifted. In one embodiment, the process controller 300 may be configured to provide a signal to the vacuum gear actuator 230 for lifting up the vacuum gear (210, 220) while maintaining the first vacuum suction and while maintaining the second vacuum suction after the predetermined duration of time that follows the detection of the delamination.

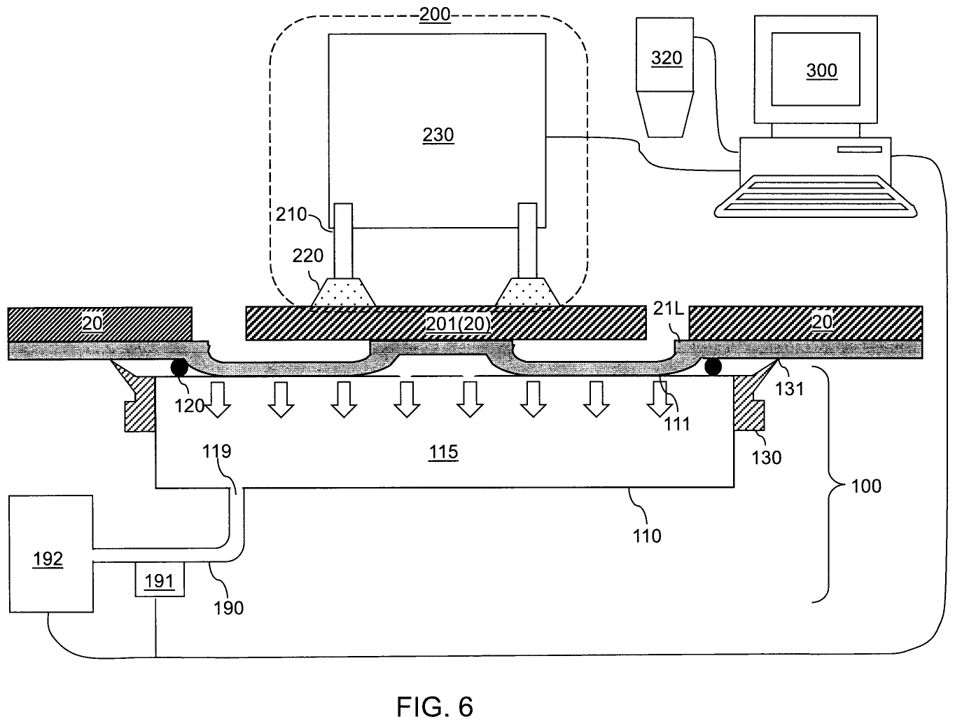

FIG. 6 is a vertical cross-sectional view of the semiconductor package pick-up apparatus during a middle phase of peeling the portion of the adhesion film 21L underneath the semiconductor package 20 in an alternative operational mode according to an embodiment of the present disclosure.

Referring to FIG. 6, the first semiconductor package 201 does not need to be a semiconductor package 20 located at an end of a one-dimensional array of semiconductor packages 20. Generally, the first semiconductor package 201 that may be picked up using the processing steps described with reference to FIGS. 1A-5 may be any semiconductor package 20 located within a row of semiconductor packages 20 as provided on an adhesion film 21L comprising an adhesion tape. In this embodiment, additional semiconductor packages 20 may be present on two sides of the first semiconductor package 201 during detachment of the first semiconductor package 201 from the adhesion film 21L.

Generally, the adhesion film 21L may comprise an adhesion tape on which a one-dimensional array of semiconductor packages 20 is attached, as an adhesion layer on which a two-dimensional array of semiconductor packages 20 is attached, or as any adhesion material portion on which one or more semiconductor package 20 is attached.

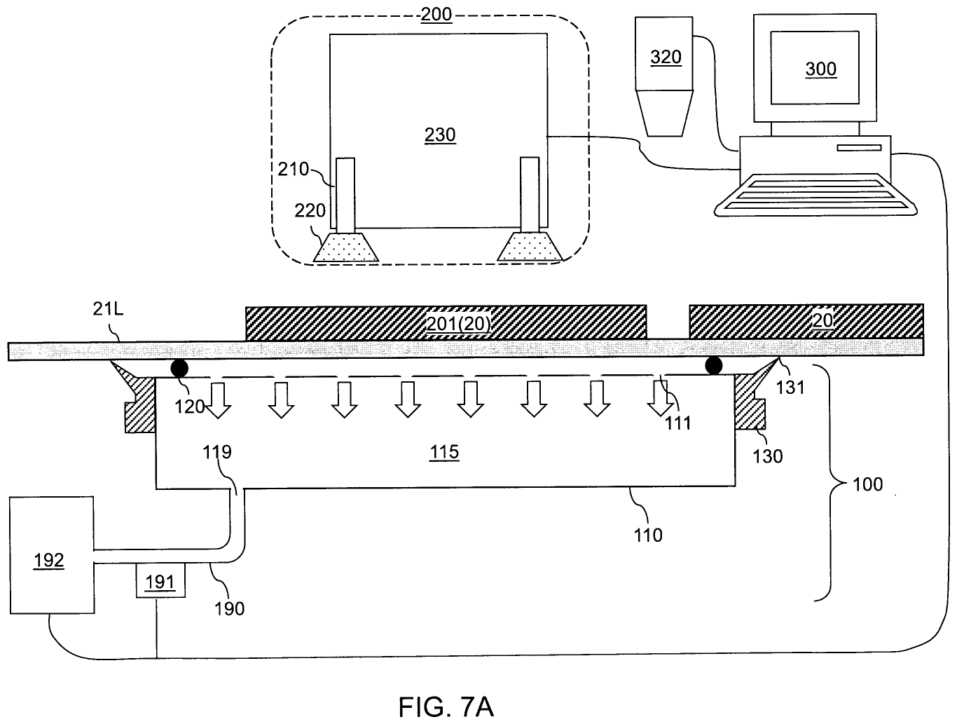

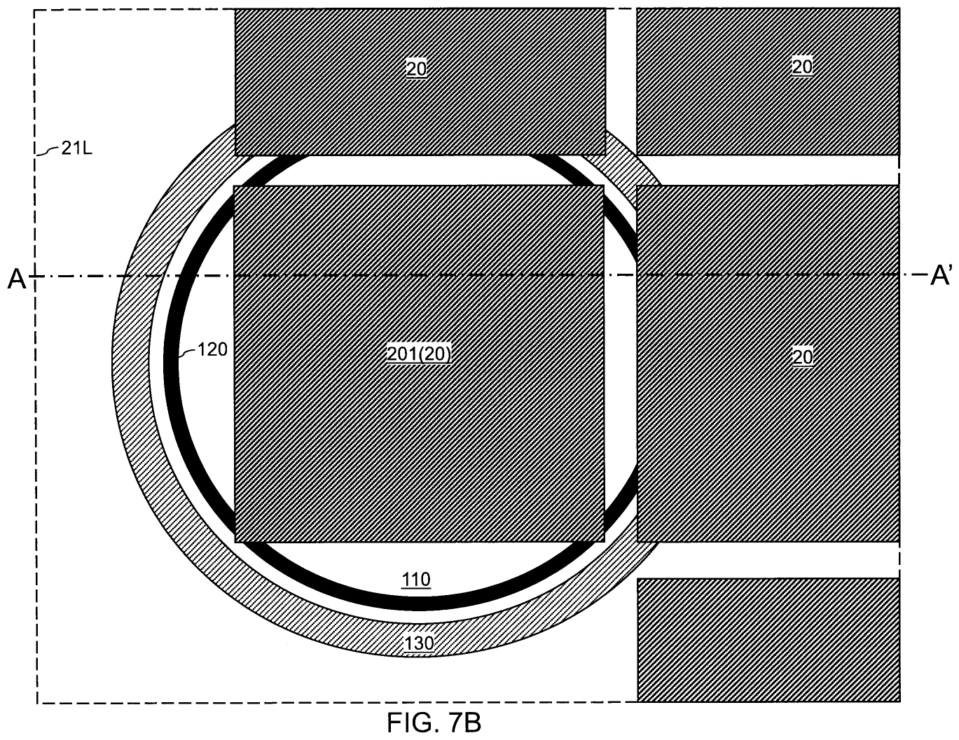

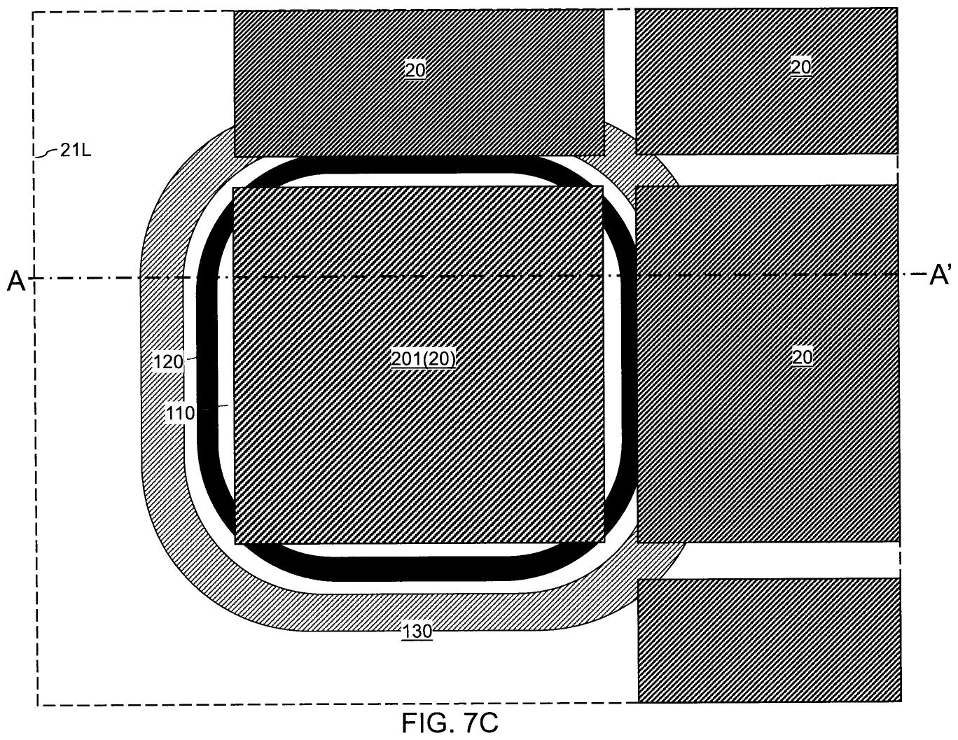

FIG. 7A is a vertical cross-sectional view of a semiconductor package pick-up apparatus after placement and alignment of a two-dimensional array of semiconductor packages 20 on an adhesion film 21L over a pepper pot according to an embodiment of the present disclosure. FIG. 7B is a see-through top-down view of the semiconductor package pick-up apparatus of FIG. 7A. The adhesion film 21L is schematically represented by a dotted area. A top suction gear is omitted in the view of

FIG. 7B. FIG. 7C is a see-through top-down view of an alternative configuration of the semiconductor package pick-up apparatus of FIG. 7A. The adhesion film 21L is schematically represented by a dotted area. A top suction gear is omitted in the view of FIG. 7B.

Referring to FIGS. 7A-7C, the adhesion film 21L may comprise an adhesion layer, and a two-dimensional array of semiconductor packages 20 may be attached to the adhesion film 21L. In this embodiment, the semiconductor packages 20 may be detached row by row, or by column by column. Further, the semiconductor packages 20 within a same row or within a same column may be detached from one side to another, or by random selection within the respective row or within the respective column.

Alternatively, the semiconductor packages 20 within the two-dimensional array of semiconductor packages 20 may be picked up in random order. The configuration illustrated in FIGS. 7A-7C corresponds to an embodiment in which the semiconductor packages 20 are picked column by column, and in which the semiconductor packages 20 are picked from one side to another within each column. The methods described with reference to FIGS. 1A-1E may be used to align a semiconductor package 20 to be picked to the pedestal 110, the first support ring 120, and the second support ring 130.

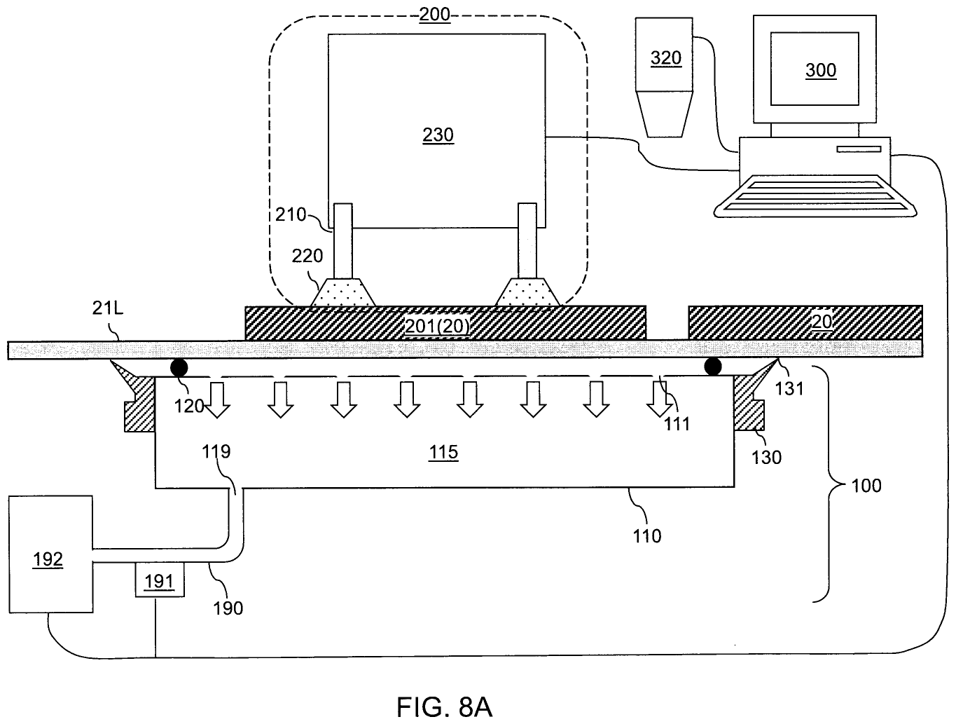

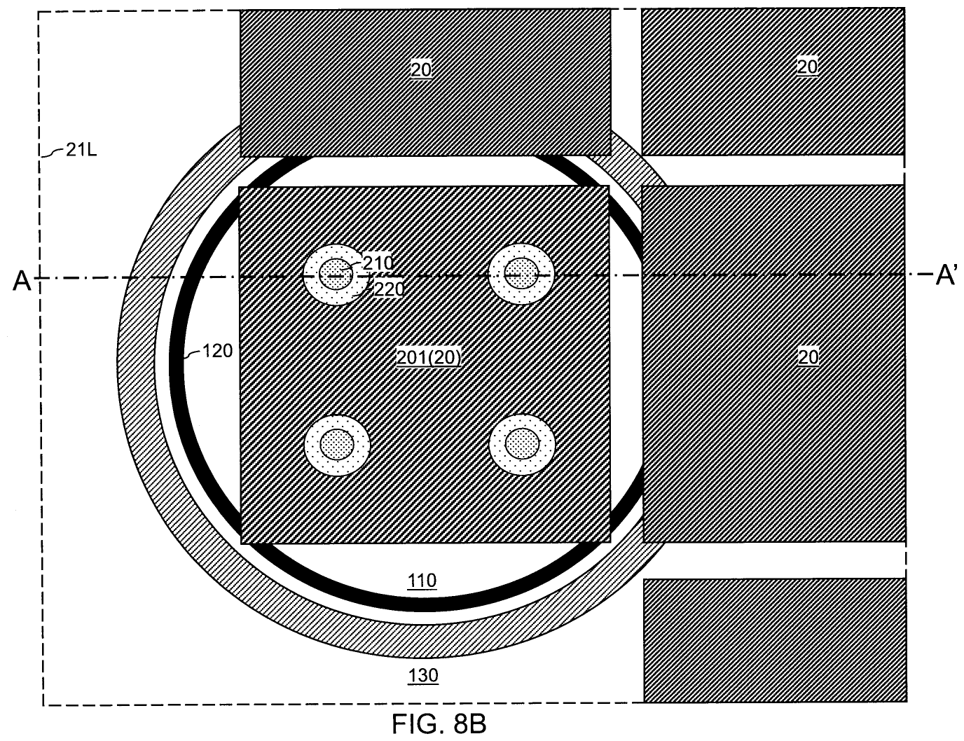

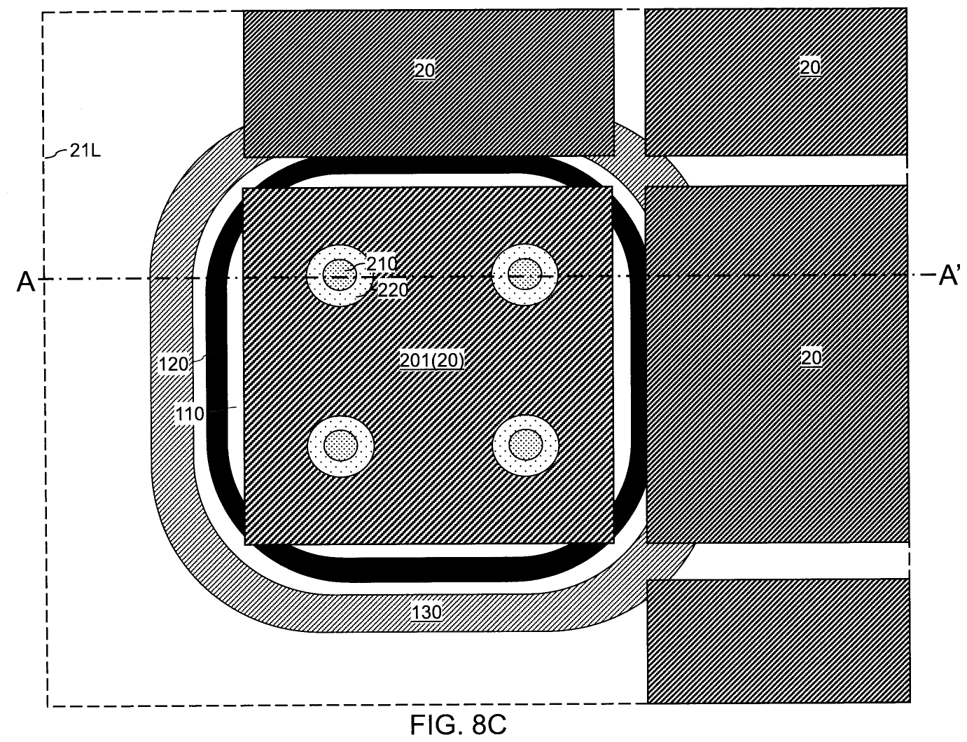

FIG. 8A is a vertical cross-sectional view of the semiconductor package pick-up apparatus after placing and actuating the top suction gear on a semiconductor package 20 according to an embodiment of the present disclosure. FIG. 8B is a see-through top-down view of the semiconductor package pick-up apparatus of FIG. 8A. The adhesion film 21L is schematically represented by a dotted area. FIG. 8C is a see-through top-down view of an alternative configuration of the semiconductor package pick-up apparatus of FIG. 8A. The adhesion film 21L is schematically represented by a dotted area.

Referring to FIGS. 8A-8C, in embodiments in which the configuration illustrated in FIGS. 7A-7C is used, the processing steps described with reference to FIGS. 2A-2C may be performed to fix the location of the first semiconductor package 201, and to apply vacuum suction to the volume within the enclosure of the pedestal 110 and the gap defined by the bottom surface of the adhesion film 21L and the first support ring 120.

Subsequently, the processing steps described with reference to FIGS. 3, 4, and 5 may be performed to detach the first semiconductor package 201 from the adhesion film 21L.

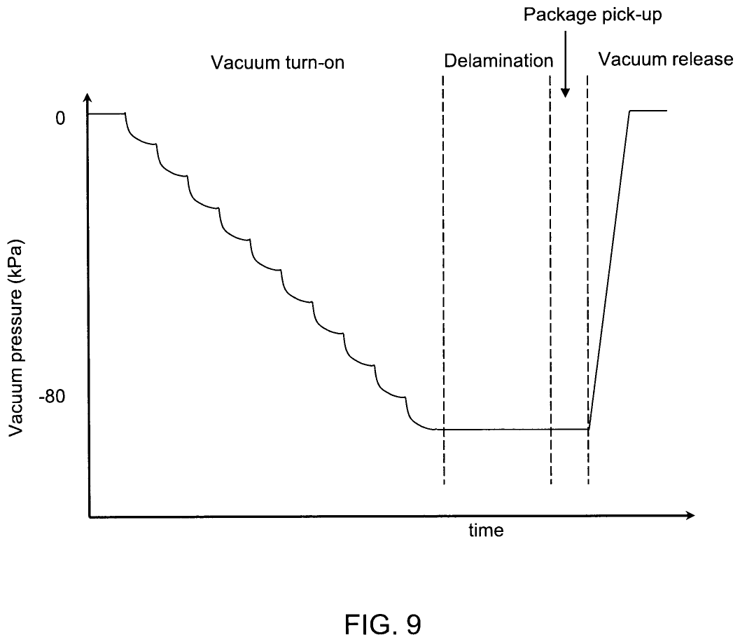

FIG. 9 is a graph illustrating the changes in the pressure in an enclosure within a pepper pot of the semiconductor package pick-up apparatus of the present disclosure during peeling of a portion of an adhesion film 21L according to an embodiment of the present disclosure.

Referring to FIG. 9, the temporal profile of the pressure applied to the volume including the enclosed volume 115 and the gap bounded by a bottom surface of the adhesion film 21L and the first support ring 120 (and the perforated top surface of the pedestal 110) is illustrated.

The vacuum turn-on step corresponds to the processing steps described with reference to FIGS. 2A-2C. In one embodiment, the process controller 300 (illustrated in FIGS. 1A-8A) may be loaded with a vacuum suction control program that is configured to provide a temporally-increasing change in a magnitude of the vacuum suction applied to the enclosed volume 115 and the gap bounded by a bottom surface of the adhesion film 21L and the first support ring 120 during operation of the semiconductor package pick-up apparatus of the present disclosure. In one embodiment, the optical camera 320 and the image analysis program loaded onto the process controller 300 may be used to control progression of the various steps during operation of the semiconductor package pick-up apparatus of the present disclosure. As discussed above, the image analysis program may be configured to detect delamination of an adhesion film 21L from the first semiconductor package 201, and may be used to commence the delamination step that follows the vacuum turn-on step.

In one embodiment, the process controller 300 (illustrated in FIGS. 1A-8A) may be configured to provide the temporally-increasing change in the magnitude of the vacuum suction that is applied to the enclosed volume 115 and the gap bounded by a bottom surface of the adhesion film 21L and the first support ring 120 until detection of the delamination. Further, the process controller 300 may be configured to maintain the magnitude of the vacuum suction at a constant level upon detection of the delamination. Generally, the temporally-increasing change in the magnitude of the vacuum suction may be stepwise, and/or may be continuous. Generally, any functional form may be used for the magnitude of the vacuum suction provided to the enclosed volume 115 and the gap bounded by a bottom surface of the adhesion film 21L and the first support ring 120 provided that the magnitude of the vacuum suction generally increasing in time until detection of delamination.

Upon detection of delamination of the adhesion film 21L from the first semiconductor package 201, the delamination step may commence. The delamination step corresponds to the processing steps described with reference to FIGS. 3, 4, and 5.

The package pick-up step corresponds to a processing step that follows the processing step of FIG. 5, in which the vacuum gear actuator 230 picks up the first semiconductor package 201 by raising up the first semiconductor package 201. In one embodiment, the process controller 300 may be configured to provide a signal to the vacuum gear actuator 230 for lifting up the vacuum gear (210, 220) after a predetermined duration of time that follows the detection of the delamination while maintaining a first vacuum suction to the vacuum gear (210, 220) and while maintaining a second vacuum suction to the enclosed volume 115 and the gap bounded by a bottom surface of the adhesion film 21L and the first support ring 120.

The vacuum release step follows the package pick-up step, in which the vacuum suction applied to the volume within the enclosure of the pedestal 110 and to the backside of the adhesion film 21L is released.

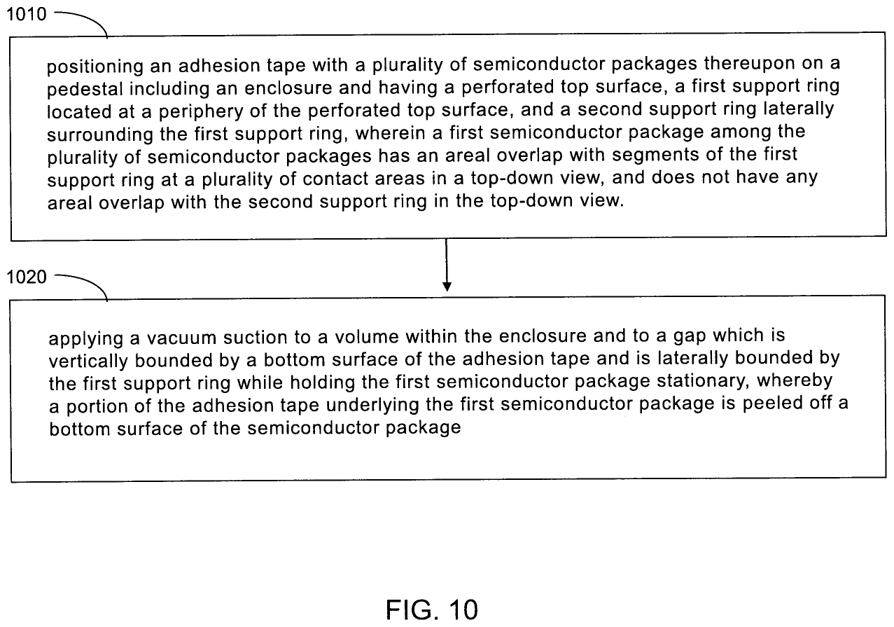

Referring to FIG. 10, a first flowchart illustrates steps for operating the semiconductor package pick-up apparatus according to an embodiment of the present disclosure.

Referring to step 1010 and FIGS. 1A-1E and 7A-7C, an adhesion film 21L with a plurality of semiconductor packages 20 thereupon may be positioned on a pedestal 110 including an enclosure and having a perforated top surface, a first support ring 120 located at a periphery of the perforated top surface, and a second support ring 130 laterally surrounding the first support ring 120. A first semiconductor package 201 selected from the plurality of semiconductor packages 20 has an areal overlap with segments of the first support ring 120 at a plurality of overlap areas in a top-down view, and does not have any areal overlap with the second support ring 130 in the top-down view.

Referring to step 1020 and FIGS. 2A-2C, 3, 4, 5, 6, 8A-8C, and 9, a vacuum suction may be applied to a volume within the enclosure and to a gap which is vertically bounded by a bottom surface of the adhesion film 21L and is laterally bounded by the first support ring 120 while holding the first semiconductor package 201 stationary. A portion of the adhesion film 21L underlying the first semiconductor package 201 is peeled off a bottom surface of the semiconductor package 20.

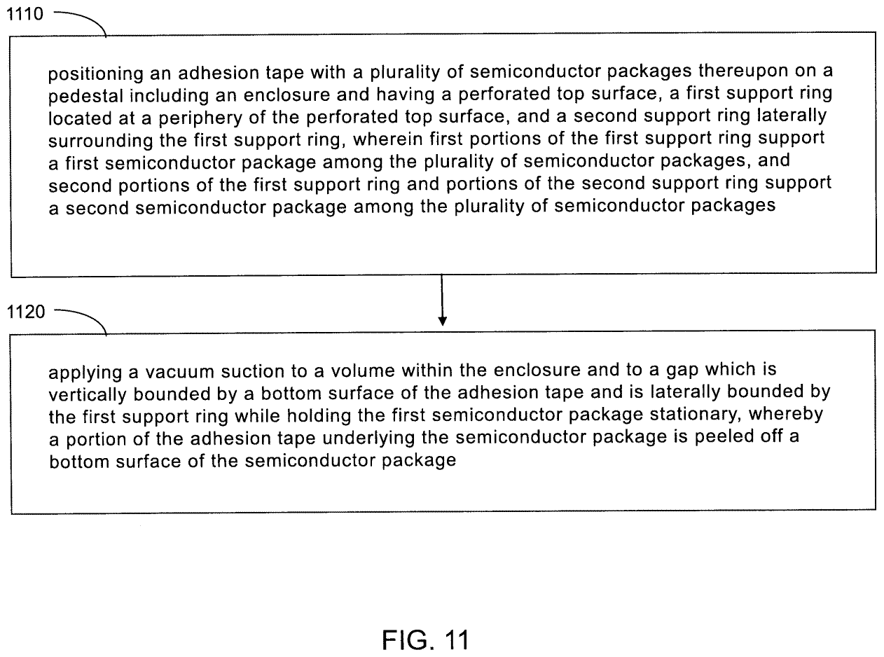

Referring to FIG. 11, a second flowchart illustrates steps for operating the semiconductor package pick-up apparatus according to an embodiment of the present disclosure.

Referring to step 1110 and FIGS. 1A-1E and 7A-7C, an adhesion film 21L with a plurality of semiconductor packages 20 thereupon may be positioned on a pedestal 110 including an enclosure and having a perforated top surface, a first support ring 120 located at a periphery of the perforated top surface, and a second support ring 130 laterally surrounding the first support ring 120. First portions of the first support ring 120 support a first semiconductor package 201 selected from the plurality of semiconductor packages 20, and second portions of the first support ring 120 and portions of the second support ring 130 support a second semiconductor package 202 selected from the plurality of semiconductor packages 20.

Referring to step 1120 and FIGS. 2A-2C, 3, 4, 5, 6, 8A-8C, and 9, a vacuum suction may be applied to a volume located inside the enclosure and a gap which is vertically bounded by a bottom surface of the adhesion film 21L and is laterally bounded by the first support ring 120 while holding the first semiconductor package 201 stationary. A portion of the adhesion film 21L underlying the semiconductor package 20 is peeled off a bottom surface of the semiconductor package 20.

Referring to all drawings and according to various embodiments of the present disclosure, a semiconductor package pick-up apparatus is provided, which comprises: a pedestal 110 including an enclosure and having a perforated top surface, wherein the enclosure is connected to a vacuum line 190 that is connected to a vacuum pump 192; a first support ring 120 located at a periphery of the perforated top surface; a second support ring 130 located at an upper portion of an outer sidewall of the pedestal 110 and laterally surrounding the first support ring 120; a vacuum gear (210, 220) configured to provide a first vacuum suction to a top surface of a substrate and located above the pedestal 110; a vacuum gear actuator 230 configured to provide a vertical movement to the vacuum gear (210, 220); and a process controller 300 configured to apply a second vacuum suction to a volume located inside the enclosure, to initiate and to terminate the first vacuum suction, and to control the vacuum gear actuator 230.

Generally, the semiconductor package pick-up apparatus may be used to pick up semiconductor packages of any type. The changes in the lateral dimensions of the semiconductor packages to be picked up may be accommodated by changing the dimensions and/or shaped of the first support ring 120 and/or the second support ring 130, and/or by changing the lateral dimensions of the pedestal 110 (which is also referred to as a pepper pot). Embodiments of the present disclosure may be used with any type of adhesion film provided the peeling force per area is less than the magnitude of the atmospheric pressure. The force applied to the backside of the adhesion film 21L may be automatically adjusted during operation of the semiconductor package pick-up apparatus based on the peeling force per area of the adhesion film 21L that is used through use of the incremental increase in the vacuum suction applied to the backside of the adhesion film 21L, and detection of the delamination of the adhesion film 21L by optical means. Thus, the semiconductor package pick-up apparatus of the present disclosure may reliably pick up semiconductor packages with minimal stress on the semiconductor packages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of picking a semiconductor package, the method comprising:
positioning an adhesion film with a plurality of semiconductor packages thereupon on a pedestal including an enclosure and having a perforated top surface, a first support ring located at a periphery of the perforated top surface, and a second support ring laterally surrounding the first support ring, wherein a first semiconductor package selected from the plurality of semiconductor packages has an areal overlap with segments of the first support ring at a plurality of overlap areas in a top-down view, and does not have any areal overlap with the second support ring in the top-down view; and
applying a vacuum suction to a volume within the enclosure and to a gap which is vertically bounded by a bottom surface of the adhesion film and is laterally bounded by the first support ring while holding the first semiconductor package stationary, whereby a portion of the adhesion film underlying the first semiconductor package is peeled off a bottom surface of the first semiconductor package.

2. The method of claim 1, wherein the first semiconductor package is positioned such that corner portions of the first semiconductor package are located between the first support ring and the second support ring in the top-down view.

3. The method of claim 1, wherein sidewalls of the first semiconductor package comprise segments that are located within an area defined by an inner periphery of the first support ring in a top-down view upon positioning the adhesion film on the pedestal.

4. The method of claim 1, wherein the plurality of overlap areas are located at four corner regions of the first semiconductor package in a top-down view.

5. The method of claim 1, wherein the first semiconductor package is positioned such that an entirety of the first semiconductor package is located within an area defined by an inner periphery of the second support ring in a top-down view.

6. The method of claim 1, wherein the first support ring has a circular or elliptical vertical cross-sectional profile.

7. The method of claim 1, wherein the second support ring has a vertical cross-sectional profile in which a lateral width between an inner sidewall and an outer sidewall decreases with a vertical distance from a horizontal plane including a bottom surface of the pedestal.

8. The method of claim 1, wherein the first semiconductor package is held stationary by positioning a vacuum gear onto a top surface of the first semiconductor package, and applying an additional vacuum suction to the top surface of the first semiconductor package.

9. The method of claim 1, wherein the vacuum suction is applied with a temporal change such that a magnitude of a force applied to a portion of the adhesion film that underlies the first semiconductor package increases until local peeling of the adhesion film begins to peel at a periphery of the bottom surface of the first semiconductor package.

10. The method of claim 1, further comprising lifting the first semiconductor package while the vacuum suction is applied, whereby portions of the adhesion film overlying the first support ring are detached as the first semiconductor package is lifted.

11. The method of claim 1, wherein the adhesion film is positioned such that a portion of the first support ring and a portion of the second support ring underlie, and support, a second semiconductor package selected from the plurality of semiconductor packages.

12. The method of claim 11, wherein a portion of the adhesion film located between the first semiconductor package and the second semiconductor package comprises:
a first area located inside the first support ring;
second areas having a respective areal overlap with the first support ring in a top-down view; and
third areas located outside the first support ring, wherein the vacuum suction is applied to a segment of the adhesion film located in the first area and is not applied to segment of the adhesion film located in the third area.

13. A method of picking a semiconductor package, the method comprising:
positioning an adhesion film with a plurality of semiconductor packages thereupon on a pedestal including an enclosure and having a perforated top surface, a first support ring located at a periphery of the perforated top surface, and a second support ring laterally surrounding the first support ring, wherein first portions of the first support ring support a first semiconductor package selected from the plurality of semiconductor packages, and second portions of the first support ring and portions of the second support ring support a second semiconductor package selected from the plurality of semiconductor packages; and
applying a vacuum suction to a volume within the enclosure and to a gap which is vertically bounded by a bottom surface of the adhesion film and is laterally bounded by the first support ring while holding the first semiconductor package stationary, whereby a portion of the adhesion film underlying the first semiconductor package is peeled off a bottom surface of the first semiconductor package.

14. The method of claim 13, further comprising increasing a magnitude of the vacuum suction until local peeling of the adhesion film begins to peel at a periphery of the bottom surface of the first semiconductor package.

15. The method of claim 14, further comprising:
optically monitoring a portion of the adhesion film that is not covered by the first semiconductor package and is proximate to the first semiconductor package while increasing the magnitude of the vacuum suction; and
holding the magnitude of the vacuum suction at a steady value upon detection of commencement of peeling off of the adhesion film within an optically monitored portion of the adhesion film.

16. A semiconductor package pick-up apparatus comprising:
a pedestal including an enclosure and having a perforated top surface, wherein the enclosure is connected to a vacuum line that is connected to a vacuum pump;
a first support ring located at a periphery of the perforated top surface;
a second support ring located at an upper portion of an outer sidewall of the pedestal and laterally surrounding the first support ring;
a vacuum gear configured to provide a first vacuum suction to a top surface of a substrate and located above the pedestal;
a vacuum gear actuator configured to provide a vertical movement to the vacuum gear; and
a process controller configured to apply a second vacuum suction to a volume located inside the enclosure, to initiate and to terminate the first vacuum suction, and to control the vacuum gear actuator.

17. The semiconductor package pick-up apparatus of claim 16, wherein:
the first support ring has a circular or elliptical vertical cross-sectional profile; and
the second support ring has a vertical cross-sectional profile in which a lateral width between an inner sidewall and an outer sidewall decreases with a vertical distance from a horizontal plane including a bottom surface of the pedestal.

18. The semiconductor package pick-up apparatus of claim 16, wherein the process controller is loaded with a vacuum suction control program that is configured to provide a temporally-increasing change in a magnitude of the second vacuum suction during operation.

19. The semiconductor package pick-up apparatus of claim 18, further comprising:
an optical camera; and
an image analysis program loaded onto the process controller and configured to detect delamination of an adhesion film from a semiconductor package,
wherein the process controller is configured to provide the temporally-increasing change in the magnitude of the second vacuum suction until detection of the delamination, and is configured to maintain the magnitude of the second vacuum suction at a constant level upon detection of the delamination.

20. The semiconductor package pick-up apparatus of claim 19, wherein the process controller is configured to provide a signal to the vacuum gear actuator for lifting up the vacuum gear after a predetermined duration of time that follows the detection of the delamination while maintaining the first vacuum suction and while maintaining the second vacuum suction.
